(19) United States
(12) Patent Application Publication
(10) Pub. No.: US 2021/0281793 A1
(43) Pub. Date: Sep. 9, 2021

(54) IMAGING SYSTEMS HAVING IMPROVED ANALOG-TO-DIGITAL CONVERTER CIRCUITRY

(71) Applicant: SEMICONDUCTOR COMPONENTS INDUSTRIES, LLC, Phoenix, AZ (US)

(72) Inventor: Carl LUYPAERT, Eppegem (BE)

(73) Assignee: SEMICONDUCTOR COMPONENTS INDUSTRIES, LLC, Phoenix, AZ (US)

(21) Appl. No.: 16/811,511

(22) Filed: Mar. 6, 2020

(51) Int. Cl. H04N 5/3745; H04N 5/345; H01L 27/146

(52) U.S. Cl. CPC H04N 5/37455; H01L 27/14609; H04N 5/345

(57) ABSTRACT

An image sensor may include an array of image pixels coupled to analog-to-digital conversion circuitry. To reduce space on the integrated circuit on which the image sensor is formed, the analog-to-digital conversion circuitry may have at least some portions that are shared between columns of the array of image pixels. In particular, individual delta-sigma modulators may be coupled to each column of the pixels to convert the charge generated by the pixels into digital bits, and shared accumulator circuitry may convert the digital bits into a digital signal. The shared accumulator circuitry may use pre-determined weights to reduce the number of required accumulation steps, and sequentially process the bits corresponding to two or more columns of the pixels. The digital signal may be stored in a shift register to further reduce the area required for the analog-to-digital conversion circuitry.

### BACKGROUND

This relates generally to imaging systems and, more particularly, to signal processing circuitry having improved analog-to-digital converter (ADC) circuitry to reduce area requirements for the ADC circuitry.

Modern electronic devices such as cellular telephones, cameras, and computers often include camera modules having digital image sensors. An image sensor (sometimes referred to as an imager) is formed from a two-dimensional array of image sensing pixels. Each pixel receives incident photons (light) and converts the photons into electrical signals.

Capturing images using an image sensor involves using reading out pixel signals from a subset of pixels from the two-dimensional image sensing pixel arrays (sometimes referred to as a “readout operation” of an image sensor). Pixel signals may be routed or otherwise provided to signal processing circuitry during the readout operation. A readout operation may be said to conclude when the signal processing circuitry that receives the image pixel signals converts the image pixel signals to digital image data.

Converting pixel signals from analog signals to digital data is accomplished by analog-to-digital converter (ADC) circuitry. In conventional imaging systems, the ADC circuitry includes higher-order delta-sigma modulators that generate bits of digital data in response to the charge generated by the pixels. In general, these higher-order delta-sigma modulators require a high oversampling ratio (OSR). For example, for a third-order delta-sigma design, over one-hundred samples may be required to generate a 16-bit signal value (due to the use of high oversampling followed by a decimation filter). Each column of pixels within the pixel array may have its own ADC circuitry and may process the readout of each column at the same time (i.e., in parallel). The ADC circuitry may require a large area to store all of the bits required and to perform the parallel processing. Moreover, a third-order decimation filter typically requires three accumulator stages, each having its own adder and storage circuitry, which may also require a large area.

It would therefore be desirable to provide improved signal processing circuitry with ADCs that require less area than conventional ADCs.

### BRIEF DESCRIPTION OF THE DRAWINGS

FIG. 1 is a schematic diagram of an illustrative imaging system with an image sensor having image sensor pixels in accordance with an embodiment.

FIG. 2 is a simplified block diagram of an imager in accordance with an embodiment.

FIG. 3 is a schematic diagram of an imager having ADC circuitry shared between columns of pixels in a pixel array in accordance with an embodiment.

FIG. 4 is a flowchart of an illustrative method in which ADC circuitry shared between pixel columns may be used to produce digital image signals in accordance with an embodiment.

FIG. 5 is a schematic diagram of ADC circuitry shared between multiple columns of image pixels and having shared accumulator, adder, and storage circuitry in accordance with an embodiment.

### DETAILED DESCRIPTION

Embodiments of the present invention relate to signal processing circuitry having ADCs with shared accumulator, adder, and/or storage circuitry to reduce the area required to convert analog signals generated by image pixels into digital signals.

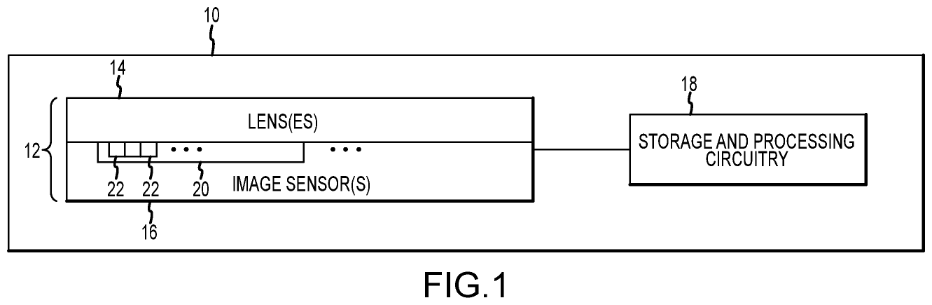

An electronic device with a digital camera module is shown in FIG. 1. Electronic device 10 of FIG. 1 may be a portable electronic device such as a camera, a cellular telephone, a tablet computer, a webcam, a video camera, a video surveillance system, a surveillance camera that takes still images, an automotive imaging system, a video gaming system with imaging capabilities, or any other desired imaging system or device that captures digital image data. Camera module 12 (sometimes referred to as an imaging device) may include image sensor 16 and one or more lenses 14. During operation, lenses 14 (sometimes referred to as optics 14) may focus light onto image sensor 16. Image sensor 16 includes photosensitive elements (e.g., pixels) in which photogenerated charges are produced in response to the light incident to the pixels. Image sensors may have any number of pixels (e.g., hundreds, thousands, millions, or more). A typical image sensor may, for example, have millions of pixels (e.g., megapixels). As examples, image sensor 16 may include bias circuitry (e.g., source follower load circuits), sample and hold circuitry, correlated double sampling (CDS) circuitry, amplifier circuitry, analog-to-digital (ADC) converter circuitry, data output circuitry, memory (e.g., buffer circuitry), address circuitry, etc.

Still and video image data from image sensor 16 may be provided to image processing and data formatting circuitry 18. Image processing and data formatting circuitry 18 may be used to perform image processing functions such as automatic focusing functions, depth sensing, data formatting, adjusting white balance and exposure, implementing video image stabilization, face detection, etc.

Image processing and data formatting circuitry 18 may also be used to compress raw camera image files if desired (e.g., to Joint Photographic Experts Group or JPEG format). In a typical arrangement, which is sometimes referred to as a system on chip (SOC) arrangement, camera sensor 16 and image processing and data formatting circuitry 18 are implemented on a common integrated circuit. The use of a single integrated circuit to implement camera sensor 16 and image processing and data formatting circuitry 18 can help to reduce costs. This is, however, merely illustrative. If desired, camera sensor 16 and image processing and data formatting circuitry 18 may be implemented using separate integrated circuits.

Although image processing and data formatting circuitry 18 has been shown as separate from camera module 12, at least a portion of processing circuitry 18 may be included within camera module 12, if desired. Additionally or alternatively, a portion of processing circuitry 18 may be included within external equipment, such as an external computer, if desired.

Camera module 12 may also convey acquired image data to host subsystems external from image sensor 16 and processing circuitry 18, if desired. Electronic device 10 typically provides a user with numerous high-level functions. In a computer or advanced cellular telephone, for example, a user may be provided with the ability to run user applications. To implement these functions, device 10 may include additional processing circuitry, and input devices such as keypads, input-output ports, joysticks, and displays. The additional processing circuitry in device 10 may include volatile and nonvolatile memory (e.g., random-access memory, flash memory, hard drives, solid state drives, etc.), and may include microprocessors, microcontrollers, digital signal processors, application specific integrated circuits, or other processing circuits.

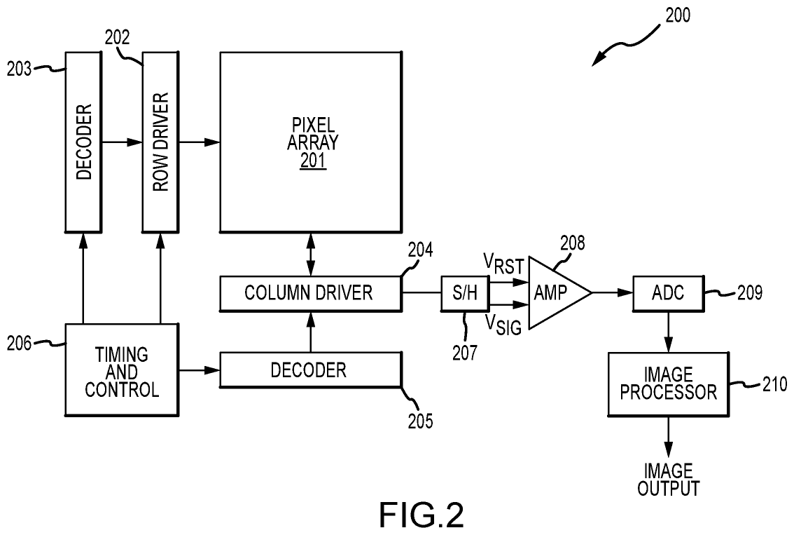

FIG. 2 illustrates a simplified block diagram of imager 200 (e.g., an image sensor such as image sensor 16 of FIG. 1). Pixel array 201 includes a plurality of pixels containing respective photosensitive elements or regions arranged in a predetermined number of columns and rows. The row lines that are coupled to the pixels may be selectively activated by row driver 202 in response to row address decoder 203 and the column select lines may be selectively activated by column driver 204 in response to column address decoder 205. Thus, a row and column address may be provided for each pixel. Row driver 202 and column driver 204 may be activated in accordance with electronic rolling shutter readout methods, or global shutter readout methods in imagers 200 that support rolling shutter readouts.

Imager 200 is operated by a timing and control circuit 206, which controls decoders 203, 205 for selecting the appropriate row and column lines for pixel readout, and row and column driver circuitry 202, 204, which apply driving voltages to the drive transistors of the selected row and column lines. The pixel signals, which typically include a pixel reset signal Vrst and a pixel image signal Vsig for each pixel are sampled by sample and hold circuitry 207 associated with the column driver 204. A differential signal Vrst-Vsig is produced for each pixel, which is amplified by amplifier 208 and digitized by analog-to-digital converter 209. The analog to digital converter 209 converts the analog pixel signals to digital signals, which are fed to image processor 210 which forms a digital image.

Analog-to-digital converter 209 may, in contrast to conventional ADC circuits, share circuitry between columns of pixels of pixel array 201. For example, each column of pixels within array 201 may be coupled to a delta-sigma modulator, and each delta-sigma modulator may then be coupled to circuitry shared across more than one column. For example, the shared circuitry may be shared between more than two columns of pixels, more than three columns of pixels, fewer than ten columns of pixels, or more than four columns of pixels, as examples. In general, the circuitry may be shared between any desired number of columns of pixels.

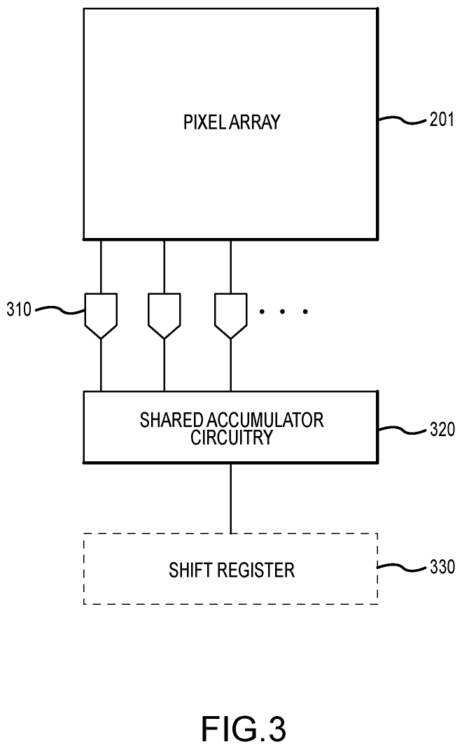

The shared circuitry may include some or all of the traditional circuitry included in ADCs. For example, the shared circuitry may include accumulator circuitry, adder circuitry, and/or shift-register storage circuitry. In general, the shared circuitry may include any combination of these circuitry components or any other desired circuitry components. By sharing ADC circuitry between pixel columns, the area required to perform analog-to-digital conversion within an imaging device may be reduced. An example of an imaging system having shared ADC circuitry between pixel columns is shown in FIG. 3.

As shown in FIG. 3, pixel array 201 may be coupled to delta-sigma modulators 310. In particular, each delta-sigma modulator may be coupled to a given column of pixels of pixel array 201. However, this is merely illustrative. Other arrangements may be used if desired. Each delta-sigma modulator 310 may in turn be coupled to shared accumulator circuitry 320. Using shared accumulator circuitry 320 rather than individual accumulator circuitry for each column of pixels may allow for a reduction in the area required to implement the image sensor and processing circuitry on an integrated circuit.

In addition to being shared between pixel columns, accumulator circuitry 320 may further be designed to have a reduced area on an integrated circuit. For example, rather than using three accumulators to perform a third-order decimation, pre-calculated weights may be used by accumulator circuitry 320 to provide an approximation of a third-order decimation. These pre-calculated weights may be selected for each individual ADC within the processing circuitry (e.g., the pre-calculated weights may vary across the columns of pixels), or the pre-calculated weights may be constant for each column of pixels across the array. Additionally or alternatively, adder circuitry within accumulator circuitry 320 may be designed to reduce the area required to implement the circuitry. As discussed, the adder circuitry may use the pre-calculated weights rather than values obtained from separate modulator steps. In one example, the adder circuitry may also utilize hybrid weight addition, performing the addition using parallel adder circuitry, rather than a single adder, which may exponentially reduce the required area (e.g., a 2^{N} reduction of area). However, this is merely illustrative. In general, accumulator circuitry 320 may be designed in any desired manner and may use any desired addition method to reduce the area required on the integrated circuit.

Shared accumulator circuitry 320 may be coupled to optional shift register 330. Shared shift register 330 may be used to store the digital signals generated by delta-sigma modulators 310 and shared accumulator circuitry 320. For example, the shift register may have a number of registers equivalent to the number of columns that share accumulator circuitry 320. In this way, shift register 330 may sequentially store the digital signals produced by shared accumulator circuitry 320 so that the signals are in a position within the shift register that corresponds with their pixel columns when the digital signals for all of the pixel columns have been produced. However, this is merely illustrative. In general, shift register 330 may have any desired number of registers.

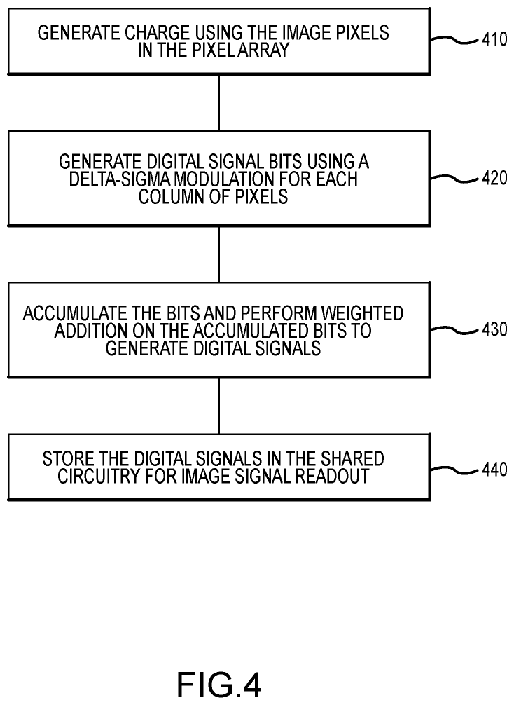

Using shift register 330 to store the digital signals generated by the ADCs may further reduce the area required to implement the processing circuitry. For example, using a shift register may allow for the omission of a multiplexer, which may reduce the area requirement of the ADCs. However, this is merely illustrative. In general, any desired circuitry may be used to store the digital signals produced by the ADCs, such as multiplexer circuitry. The ADC area reduction components described in FIG. 3 may be operated according to the method shown in FIG. 4.

As shown in FIG. 4, at step 410, image pixels in array 201 may generate charge in response to incident light. The image pixels in array 201 may be arranged in rows and columns. Because the charge generated by the image pixels is analog, each column of image pixels may be coupled to a delta-sigma modulator.

At step 420, each delta-sigma modulator may be used to generate digital signal bits from the analog charge generated by a column of the image pixels. Although each column of pixels may have a dedicated delta-sigma modulator, delta-sigma modulators may be shared between columns, if desired.

At step 430, shared accumulation circuitry 320 may be used to accumulate the bits generated by the delta-sigma modulator and perform weighted addition on the accumulated bits. As previously described, shared accumulation circuitry 320 may be coupled to multiple delta-sigma modulators and therefore receive bits that correspond to charge generated by multiple columns of pixels (e.g., shared accumulation circuitry 320 may receive bits that correspond to a first column, generate a first digital signal, and then receive bits that correspond to a second column, etc.). To reduce the area requirements for the circuitry, shared accumulation circuitry 320 may use weighted values to reduce the number of required modulation/decimation steps, and the weighted values and accumulated bits may be added using any desired scheme, such as hybrid weight addition. In this way, the bits for each column may be accumulated, converted into digital bits, and decimated into a digital signal using shared accumulation circuitry 320.

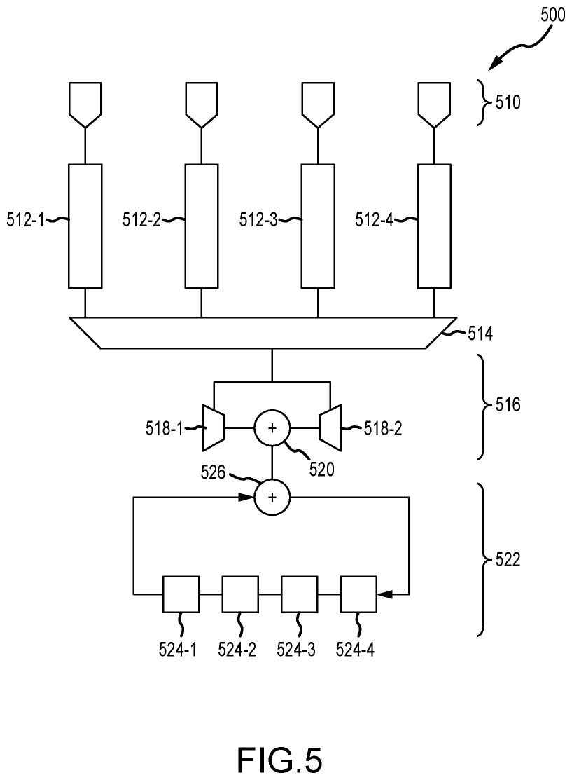

At step 440, the digital signal may be stored in shared circuitry for image signal readout. In particular, the shared circuitry may include a multiplexer, may include a shift register, or may include any other desired components. In any event, it may be desirable to store the digital signals that correspond to each of the pixel columns in the same storage circuitry to reduce the area required to implement the processing circuitry. Once the digital signals have been generated for each column of image signals and stored in the storage circuitry, the digital signals can be read out. Illustrative shared ADC circuitry that may reduce the area needed to implement the processing circuitry and that may be operated using this method is shown in FIG. 5.

As shown in FIG. 5, ADC circuitry 500 may include delta-sigma modulators 510. Each of the delta-sigma modulators 510 may be coupled to a given one pixel column of a pixel array, such as pixel array 201 of FIG. 3. However, this is not limiting. If desired, delta-sigma modulators may be shared between different pixel columns. In general, however, each column of the pixel array may be coupled to a delta-sigma modulator.

Delta-sigma modulators 510 may produce digital bits in response to charge generated by the image pixels. In one example, each delta-sigma modulator may produce one digital bit each clock cycle.

Delta-sigma modulators 510 may be coupled to shift registers 512. Each of the delta-sigma modulators may be coupled to a given one shift register (e.g., shift register 512-1) so that each shift register may store digital bits associated with a single one of the pixel columns. Shift register 512-1 may store a first number of digital bits N, shift register 512-2 may store a second number of digital bits N+1 that is one greater than the first number, shift register 512-3 may store a third number of digital bits N+2 that is two greater than the first number, and shift register 512-4 may store a fourth number of digital bits N+3 that is three greater than the first number. The first number may be equivalent to the number of columns that share the accumulator circuitry. For example, if four pixel columns share the ADC circuitry, four bits may be stored in shift register 512-1 over four clock cycles, five bits may be stored in shift register 512-2 over five clock cycles, six bits may be stored in shift register 512-3 over six clock cycles, and seven bits may be stored in shift-register 512-4 over seven clock cycles. Storing additional bits in shift registers 512-2, 512-3, and 512-4 may allow for the collection of additional bits generated for the corresponding pixel columns while the bits corresponding to the previous column(s) are decimated into a digital signal. However, this is merely illustrative. In general, shift registers 512 may store any desired number of digital bits.

Shift registers 512 may be coupled to multiplexer 514, which may feed the bits from a given one of shift registers 512 to addition circuitry 516 (e.g., referred to as shared accumulator circuitry 320 in FIG. 3). Addition circuitry 516 may utilize hybrid weighted addition (e.g., may include a hybrid weight adder). As previously discussed, addition circuitry may use pre-determined weights to provide a higher-order accumulation without adding additional accumulation steps. These pre-determined weights may be constant for every column of pixels or may vary across the columns of pixels. As shown in FIG. 5, addition circuitry 516 may use these pre-determined weights in hybrid weight addition, and may be split with first addition multiplexer 518-1 and second addition multiplexer 518-2, which may selectively pass the pre-determined weights to adder 520. Splitting addition circuitry 516 in half may reduce the area required for the ADC and processing circuitry. For example, splitting addition circuitry 516 in this way may result in a 2^{N} reduction in the area required to implement the ADC circuitry for the image sensor. However, this is merely illustrative. Addition circuitry 516 may have a single source from which the pre-determined weights are fed to adder 520, or may have more than two sources from which the pre-determined weights are fed to adder 520. In general, addition circuitry 516 may be designed in any desired manner.

After the bits generated by delta-sigma modulators 510 are converted into digital signals by shared addition circuitry 516, the digital signals may be stored in shared storage 522. In particular, as shown in FIG. 5, shared storage 522 may include shift registers 524 governed by the adder 526. The first signal (e.g., the signal generated from the digital bits stored in shift register 512-1) processed by addition circuitry 516 may be stored in storage register 524-4. After the second signal (e.g., the signal generated from the digital bits stored in shift register 512-2) is processed by addition circuitry 516, the first signal may be shifted into storage register 524-3, and the second signal may be stored in storage register 524-4. This process may be continued until the fourth signal (e.g., the signal generated from the digital bits stored in shift register 512-4) is stored in storage register 524-4 (with the first signal in register 524-1, the second signal in register 524-2, and the third signal in register 524-3). In other words, the shift register 512-4 may sequentially store the digital signals associated with each of the pixel columns. Having the digital signals stored in a shift register in this way may allow the shift registers to be arranged as a ring on the integrated circuit, reducing the area requirement that would be required with alternative storage methods. At this point, the first, second, third, and fourth digital signals may be read out to be processed by an image processor, such as image processor 210 of FIG. 2.

Although the example of FIG. 5 has described as sharing ADC circuitry between four columns of pixel array 201, this is merely illustrative. In general, ADC circuitry may be shared between two or more columns, three or more columns, fewer than ten columns, or four or more columns of pixel array 201, as desired. In general, the number of delta-sigma modulators 510, shift registers 512, and storage registers 524 may be equivalent to the number of columns that will share the circuitry, but this is merely illustrative. In general, any desired number of delta-sigma modulators, shift registers, and storage registers may be used to process the analog charge generated by image pixels, convert the charge to digital signals, and store the digital signals.

Various embodiments have been described illustrating imaging devices having shared ADC circuitry to reduce the integrated circuit area required to implement the circuitry.

In accordance with various embodiments, an image sensor may include an array of pixels arranged in rows and columns and analog-to-digital conversion circuitry coupled to the array of pixels. The pixels may generate charge in response to incident light, and the analog-to-digital conversion circuitry may include a plurality of delta-sigma modulators that convert the generated charge into digital signal bits and shared accumulator circuitry that produces a digital signal from the digital signal bits. At least two of delta-sigma modulators may be coupled to the shared accumulator circuitry, and each of the delta-sigma modulators may be coupled to one of the columns of pixels.

In accordance with some embodiments, the image sensor may further include shared storage circuitry coupled to the shared accumulator circuitry. The shared storage circuitry may store the digital signal corresponding to each of the pixel columns that are associated with the shared accumulator circuitry.

In accordance with some embodiments, the shared storage circuitry may include shift registers, and one of the shift registers may sequentially store the digital signals associated with all of the pixel columns.

In accordance with some embodiments, the image sensor may further include a plurality of additional shift registers. Each of the additional shift registers may be coupled to a given one of the delta-sigma modulators.

In accordance with some embodiments, the shared accumulator circuitry may use pre-determined weights in combination with the digital signal bits to produce the digital signal.

In accordance with some embodiments, the shared accumulator circuitry may include a hybrid weight adder that uses the pre-determined weights and the digital signal bits to produce the digital signal.

In accordance with some embodiments, the hybrid weight adder may include first and second multiplexers coupled to an adder, and the first and second multiplexers may select a given one of the pre-determined weights to send to the adder to be combined with the digital bits.

In accordance with some embodiments, the pre-determined weights may be the same for each column of pixels across the array of pixels.

In accordance with some embodiments, the pre-determined weights may vary for the columns of pixels across the array of pixels.

In accordance with some embodiments, the additional shift registers may be configured to store different numbers of digital bits based on the column of pixels with which the additional shift registers are associated.

In accordance with various embodiments, a method of operating an image sensor and processing circuitry may include generating charge in response to incident light using image pixels that are arranged in rows and columns in an array of image pixels, generating digital signal bits from the generated charge using delta-sigma modulators that are each coupled to a given one of the columns of image pixels in the array, accumulating the digital signal bits associated with a first column of the pixels, performing weighted addition using the accumulated digital signal bits associated with the first column of the pixels and pre-determined weights to produce a first digital signal, accumulating the digital signal bits associated with a second column of the pixels, and performing weighted addition using the accumulated digital signal bits associated with the second column of the pixels and pre-determined weight to produce a second digital signal.

In accordance with some embodiments, performing the weighted addition may include performing hybrid weighted addition using the accumulated digital signal bits and the pre-determined weights.

In accordance with some embodiments the method may further include after producing the first digital signal, storing the first digital signal in a first shift register, and after producing the second digital signal, shifting the first digital signal to a second shift register and storing the second digital signal in the first shift register.

In accordance with some embodiments, accumulating the digital signal bits associated with the first column of the pixels may include storing the digital signal bits in a first shift register and accumulating the digital signal bits associated with the second column of the pixels may include storing the digital signal bits in a second shift register.

In accordance with some embodiments, storing the digital signal bits in the first register may include storing a first number of digital signal bits in the first register and storing the digital signal bits in the second register may include storing a second number of digital signal bits in the second register. The second number of digital signal bits may be greater than the first number of digital signal bits.

In accordance with various embodiments, an image sensor may include an array of pixels arranged in rows and columns, a plurality of delta-sigma modulators, wherein each column of pixels is coupled to a given one of the delta-sigma modulators, and shared accumulation circuitry coupled to at least two of the delta-sigma modulators.

In accordance with some embodiments, the image sensor may further include shared storage circuitry coupled to the shared accumulation circuitry.

In accordance with some embodiments, the shared storage circuitry may include a plurality of shift registers, and the shared accumulation circuitry may include hybrid weight addition circuitry.

In accordance with some embodiments, the image sensor may further include an additional plurality of shift registers coupled between the at least two delta-sigma modulators and the shared accumulation circuitry.

In accordance with some embodiments, the delta-sigma modulators may be configured to generate digital signal bits that correspond to charge generated by the columns of the pixels, and the hybrid weight addition circuitry may be configured to generate digital signals based on the digital signal bits and pre-determined weights.

The foregoing is merely illustrative and various modifications can be made to the described embodiments. The foregoing embodiments may be implemented individually or in any combination.

What is claimed is:

1. An image sensor comprising:
an array of pixels arranged in rows and columns, wherein the pixels are configured to generate charge in response to incident light; and
analog-to-digital conversion circuitry coupled to the array of pixels, wherein the analog-to-digital conversion circuitry comprises:
a plurality of delta-sigma modulators configured to convert the generated charge into digital signal bits, wherein each of the delta-sigma modulators is coupled to one of the columns of pixels, and
shared accumulator circuitry configured to produce a digital signal from the digital signal bits, wherein at least two of delta-sigma modulators are coupled to the shared accumulator circuitry.

2. The image sensor defined in claim 1 further comprising:
shared storage circuitry coupled to the shared accumulator circuitry, wherein the shared storage circuitry is configured to store the digital signal corresponding to each of the pixel columns that are associated with the shared accumulator circuitry.

3. The image sensor defined in claim 2 wherein the shared storage circuitry comprises shift registers and wherein one of the shift registers is configured to sequentially store the digital signals associated with all of the pixel columns.

4. The image sensor defined in claim 3 further comprising:
a plurality of additional shift registers, wherein each of the additional shift registers is coupled to a given one of the delta-sigma modulators.

5. The image sensor defined in claim 4 wherein the shared accumulator circuitry is configured to use pre-determined weights in combination with the digital signal bits to produce the digital signal.

6. The image sensor defined in claim 5 wherein the shared accumulator circuitry comprises a hybrid weight adder that uses the pre-determined weights and the digital signal bits to produce the digital signal.

7. The image sensor defined in claim 6 wherein the hybrid weight adder comprises first and second multiplexers coupled to an adder, and wherein the first and second multiplexers each select a given one of the pre-determined weights to send to the adder to be combined with the digital bits.

8. The image sensor defined in claim 7 wherein the pre-determined weights are the same for each column of pixels across the array of pixels.

9. The image sensor defined in claim 7 wherein the pre-determined weights vary for the columns of pixels across the array of pixels.

10. The image sensor defined in claim 5 wherein the additional shift registers are configured to store different numbers of digital bits based on the column of pixels with which the additional shift registers are associated.

11. A method of operating an image sensor and processing circuitry, the method comprising:
generating charge in response to incident light using image pixels that are arranged in rows and columns in an array of image pixels;
generating digital signal bits from the generated charge using delta-sigma modulators that are each coupled to a given one of the columns of image pixels in the array;
accumulating the digital signal bits associated with a first column of the pixels;
performing weighted addition using the accumulated digital signal bits associated with the first column of the pixels and pre-determined weights to produce a first digital signal;
accumulating the digital signal bits associated with a second column of the pixels; and
performing weighted addition using the accumulated digital signal bits associated with the second column of the pixels and pre-determined weight to produce a second digital signal.

12. The method defined in claim 11 wherein performing the weighted addition comprises performing hybrid weighted addition using the accumulated digital signal bits and the pre-determined weights.

13. The method defined in claim 12 further comprising:
after producing the first digital signal, storing the first digital signal in a first shift register; and
after producing the second digital signal, shifting the first digital signal to a second shift register and storing the second digital signal in the first shift register.

14. The method defined in claim 11 wherein accumulating the digital signal bits associated with the first column of the pixels comprises storing the digital signal bits in a first shift register and wherein accumulating the digital signal bits associated with the second column of the pixels comprises storing the digital signal bits in a second shift register.

15. The method defined in claim 14 wherein storing the digital signal bits in the first register comprises storing a first number of digital signal bits in the first register and wherein storing the digital signal bits in the second register comprises storing a second number of digital signal bits in the second register, and wherein the second number of digital signal bits is greater than the first number of digital signal bits.

16. An image sensor comprising:
an array of pixels arranged in rows and columns;
a plurality of delta-sigma modulators, wherein each column of pixels is coupled to a given one of the delta-sigma modulators; and
shared accumulation circuitry coupled to at least two of the delta-sigma modulators.

17. The image sensor defined in claim 16 further comprising:
shared storage circuitry coupled to the shared accumulation circuitry.

18. The image sensor defined in claim 17 wherein the shared storage circuitry comprises a plurality of shift registers and wherein the shared accumulation circuitry comprises hybrid weight addition circuitry.

19. The image sensor defined in claim 18 further comprising:
an additional plurality of shift registers coupled between the at least two delta-sigma modulators and the shared accumulation circuitry.

20. The image sensor defined in claim 19 wherein the delta-sigma modulators are configured to generate digital signal bits that correspond to charge generated by the columns of the pixels and wherein the hybrid weight addition circuitry is configured to generate digital signals based on the digital signal bits and pre-determined weights.
